(19) United States
(12) Patent Application Publication
(10) Pub. No.: US 2025/0275118 A1
(43) Pub. Date: Aug. 28, 2025

(54) SEMICONDUCTOR STRUCTURE AND METHOD OF FABRICATING THE SAME

(71) Applicant: Fujian Jinhua Integrated Circuit Co., Ltd., Quanzhou City (CN)

(72) Inventors: CHAOZHEN HONG, Quanzhou City (CN); Yu-Cheng Tung, Quanzhou City (CN); Wen-Yi Wong, Quanzhou City (CN)

(73) Assignee: Fujian Jinhua Integrated Circuit Co., Ltd., Quanzhou City (CN)

(21) Appl. No.: 18/633,510

(22) Filed: Apr. 11, 2024

(30) Foreign Application Priority Data
Feb. 26, 2024 (CN) 202410212194.5

(51) Int. Cl. H10B 12/00

(52) U.S. Cl. CPC H10B 12/31; H10B 12/0335

(57) ABSTRACT

The present disclosure provides a semiconductor structure and a fabricating method thereof, including a pad array. The pad array includes a plurality of first pads, a first marginal pad, a second marginal pad, a plurality of second pads, and a plurality of third pads. The first pads are separately disposed. The first marginal pad is disposed at one side of the pad array, and includes a plurality of first branch pads. The second marginal pad is disposed at another side of the pad array being opposite to the first marginal pad, and includes a plurality of second branch pads. The second pads are separately disposed between the first branch pads. The third pads are separately disposed between the second branch pads, wherein a length of the second pads is smaller than a length of the third pads.

### BACKGROUND OF THE INVENTION

### 1. Field of the Invention

The present disclosure generally relates to a semiconductor structure and a method of fabricating the same, and more particularly, to a semiconductor structure including pads and a method of fabricating the same.

### 2. Description of the Prior Art

With the trend of miniaturization of various electronic products, the design of semiconductor devices must also meet the requirements of high integration and high density. Under the current mainstream of development trend, dynamic random access memories (DRAMs) having recessed gate structures have gradually replaced the DRAMs having only planar gate structures due to longer carrier channel length for the same semiconductor substrate so as to reduce current leakage of capacitor structures. In general, a DRAM cell with a recessed gate structure includes a transistor component and a charge storage device to receive voltage signals from bit lines and word lines. However, due to the limitations of current processing technologies, there are still many defects in currently available DRAM cells with recessed gate structures, which need to be further improved to effectively improve the performance and reliability of related memory devices.

### SUMMARY OF THE INVENTION

An object of the present disclosure is to provide a semiconductor structure and a method of fabricating the same, in which peripheral pads with various lengths are arranged at two sides of the pad array, for improving the possible structural defects on the semiconductor structure which may be caused by the continuous increased density of the DRAM cell.

In order to achieve the above object, one embodiment of the present disclosure provides a semiconductor structure including a storage node pad array. The storage node pad array includes a plurality of first pads, a first marginal pad, a second marginal pad, a plurality of second pads, and a plurality of third pads. The first pads are separately disposed in a first direction and in a second direction. The first marginal pad is disposed at one side of the storage node pad array, and includes a plurality of first branch pads extending in the first direction. The second marginal pad is disposed at another side of the storage node pad array being opposite to the first marginal pad, and includes a plurality of second branch pads extending in the second direction. The second pads are separately disposed between the first branch pads in a third direction. The third pads are separately disposed between the second branch pads in the third direction, wherein a length of the second pads in the first direction is smaller than a length of the third pads in the first direction.

In order to achieve the above object, one embodiment of the present disclosure provides a semiconductor structure including a storage node pad array. The storage node pad array includes a plurality of first pads, a first marginal pad, and a second marginal pad. The first pads are separately arranged into a plurality of columns in a first direction, and a plurality of rows in a second direction. The first marginal pad is disposed at one side of the storage node pad array, and includes a plurality of first branch pads. The second marginal pad is disposed at another side of the storage node pad array being opposite to the first marginal pad, and includes a plurality of second branch pads. The first pads within each of the columns closest to the first marginal pad includes a first zigzag profile, the first pads within each of the columns closest to the second marginal pad includes a second zigzag profile, and the second zigzag profile is different from the first zigzag profile.

In order to achieve the above object, one embodiment of the present disclosure provides a fabricating method of a semiconductor structure including the following steps. A plug array is formed on a chip, and the plug array includes a plurality of plugs each including a plug-barycenter being defined thereon. A predicted storage node pad array is defined on the chip, wherein the predicted storage node pad array includes a plurality of predicted pad patterns, and each of the predicted pad patterns includes a predicted pad-barycenter being defined thereon. A plurality of pads is formed on the plugs through the predicted storage node pad array, wherein each of the pads overlaps each of the plugs and includes a pad-barycenter. The pads are adjusted through comparing positions of the plug-barycenter, the predicted pad-barycenter, and the pad-barycenter.

Overall speaking, According to the semiconductor structure and the fabricating method thereof of the present disclosure, peripheral pads with various lengths are arranged at two opposite sides of the SN pad array, with the SN pad array presenting in an asymmetric layout as a whole, to as to maintain the contacting area between the pads and the corresponding plugs within the cell region. Thus, the semiconductor structure of the present disclosure enables to gain an optimized structure and better functions.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 to FIG. 4 are schematic diagrams illustrating a semiconductor structure according to one preferably embodiment of the present disclosure, wherein:

FIG. 1 illustrates a top view of a semiconductor structure;

FIG. 2 illustrates a cross-sectional view taken along cross lines A-A′ and B-B′;

FIG. 3 illustrates another top view of a semiconductor structure; and

FIG. 4 illustrates a partial enlarged view of FIG. 3.

FIG. 5 to FIG. 9 are schematic diagrams illustrating a fabricating method of a semiconductor structure according to one preferably embodiment of the present disclosure, wherein:

FIG. 5 illustrates a process flow of the fabricating method of the semiconductor structure;

FIG. 6 illustrates a top view of a semiconductor structure after forming a plug array, a predicted storage node pad array, and a pad array;

FIG. 7 illustrates a cross-sectional view of a semiconductor structure after forming a plug array, a predicted storage node pad array, and a pad array;

FIG. 8 illustrates a top view of a semiconductor structure after adjusting the pad array; and

FIG. 9 illustrates a cross-sectional view of a semiconductor structure after adjusting the pad array.

FIG. 10 illustrates another top view of a semiconductor structure after adjusting the pad array according to another embodiment of the present disclosure.

### DETAILED DESCRIPTION

For better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

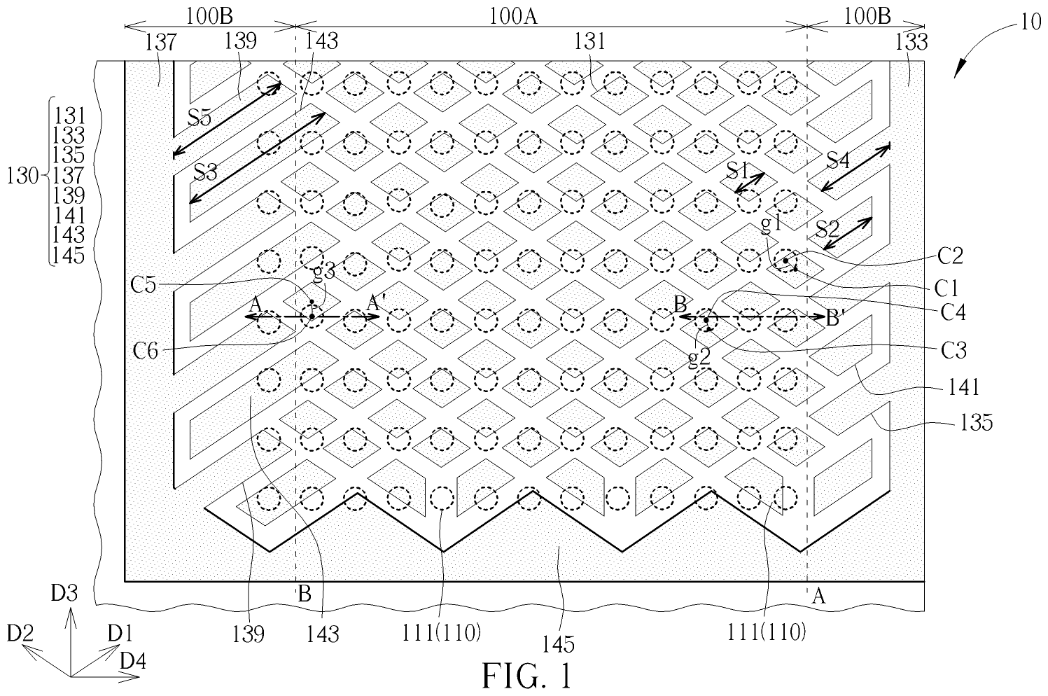

Please refer to FIG. 1 to FIG. 4, which are schematic diagrams illustrating a semiconductor structure 10 according to a preferable embodiment of the present disclosure. Firstly, as shown in FIG. 1, the semiconductor structure 10 includes a storage node (SN) pad array 130 for example including a low-resistance metal material like aluminum (Al), titanium (Ti), copper (Cu) or tungsten (W), and preferable for tungsten, but not limited. The SN pad array 130 precisely includes a plurality of first pads 131, a first marginal pad 133, a second marginal pad 137, a plurality of second pads 141 and a plurality of third pads 143. The first pads 131 are separately from each other in a first direction D1 and in a second direction D2 which are interlaced and not perpendicular to each other. The first marginal pad 133 and the second marginal pad 137 are respectively extended in a third direction D3, at two opposite sides of the SN pad array 130. The first marginal pad 133 disposed at one side of the SN pad array 130 further includes a plurality of first branch pads 135 in the first direction D1, and the second marginal pad 137 disposed at another side of the SN pad array 130 further includes a plurality of second branch pads 139 in the first direction D1. The second pads 141 are separately disposed between the first branch pads 135 in the third direction D3, and the third pads 143 are separately disposed between the second branch pads 139 in the third direction D3.

It is noted that each of the first pads 131 includes a same first length S1 in the first direction D1, and each of the second pads 141 and the third pads 143 respectively include a second length S2 and a third length S3 different from the first length S1 in the first direction D1. The second length S2 of the second pads 141 is smaller than the third length S3 of the third pads 143. Accordingly, through arranging second pads 141 and third pads 143 in various lengths (the second length S2 and the third length S3) at two opposite sides of the SN pad array 130, the SN pad array 130 will therefore present in an asymmetric layout as being viewed from a top view as shown in FIG. 1, thereby improving the possible structural defects of the semiconductor structure 10 caused by the continuous increased density of the DRAM cell. Also, in another embodiment, each of the first branch pads 135 and each of the second branch pads 139 at two opposite sides of the SN pad array 130 respectively include a fourth length S4 and a fifth length S5 different from the first length S1, and the fourth length S4 of the first branch pads 135 is smaller than the fifth length S5 of the second branch pads 139, thereby presenting in an asymmetric layout as well.

Further in view of FIG. 1, there is no first pads 131 being disposed between adjacent ones of the first branch pads 135 or the second pads 141 in the third direction D3, at one side of the SN pad array 130, and there is one of the first pads 131 being disposed between adjacent ones of the third pads 143, at another side of the SN pad array 130. Also, the end-portions of each first branch pad 135 and each second pad 141 at one side of the SN pad array 130 are aligned with each other in the third direction D3, such that, the end-portions of each first branch pad 135 and each second pad 141 are located on the same cross line “A”, as shown in FIG. 1. On the other hand, the end-portions of each second branch pad 139 and each third pad 143 are alternately arranged in the third direction D3, with the end-portions of the second branch pads 139 being aligned with each other and located on the same cross line “b”, and being misaligned with the end-portions of the third pads 143. In the preset embodiment, the first marginal pad 133, the second marginal pad 137 are respectively disposed outside all of the first pads 131, the second pads 141, and the third pads 143, so as to gain the protection on the overall arrangement of the first pads 131. Those who skilled in the art should fully realize that the semiconductor structure 10 in another embodiment may further include at least one third marginal pad 145 in a fourth direction D4, with two ends of the third marginal pad 145 respectively connecting the first marginal pad 133 and the second marginal pad 137, so that, the first marginal pad 133, the second marginal pad 137, and the third marginal pad 145 will therefore around all of the first pads 131, the second pads 141, and the third pads 143, to present in a rectangular shape or in other suitable shape, to achieve better protection.

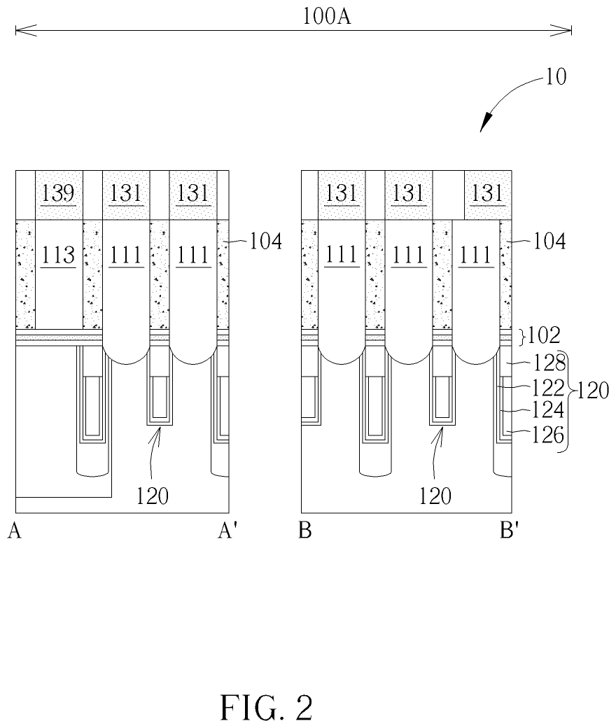

As shown in FIG. 1 and FIG. 2, the semiconductor structure 10 further includes a substrate 100 and a plurality of word lines 120 disposed within the substrate 100. The above-mentioned SN pad array 130 is disposed on the substrate 100, and the substrate 100 for example includes a silicon substrate, a silicon-containing substrate, e.g., SiC or SiGe, a silicon-on-insulator (SOI) substrate, or a substrate formed of any other suitable material, but it is not limited thereto. In principle, the first pads 131 are disposed within a cell region 100A having a relative greater integration, and the second pads 141, the first branch pads 135, the third pads 143, and the second branch pads 139 disposed at two sides of the SN pad array 130 are disposed within a periphery region 100B having a relative lower integration. In one embodiment, the periphery region 100B is for example disposed at least one side of the cell region 100A. Preferably, the periphery region 100B is for example disposed around the cell region 100A, but not limited thereto. Each of the word lines 120 separately disposed within the substrate 100, and precisely includes a dielectric layer 122, a gate dielectric layer 124, a gate 126, and a capping layer 128 covered on the gate 126, as shown in FIG. 2. The top surface of the capping layer 128 is coplanar with the top surface of the substrate 100, such that, each word line 120 may serve as a buried word line (BWL) of a semiconductor device, being isolated from other components over the substrate 100 through an insulating layer 102 disposed on the substrate 100. In one embodiment, the insulating layer 102 preferably includes a composite structure including an oxide-nitride-oxide (ONO) structure, but not limited thereto.

Further in view of FIG. 1 and FIG. 2, the semiconductor structure 10 further includes a plug array 110 also disposed on the substrate 100, and which includes a plurality of plugs 111, 113 separately arranged in the third direction D3 and in the fourth direction D4 which are perpendicular to each other, in an array arrangement as shown in FIG. 1. The plugs 111, 113 are respectively within the cell region 100A, and within the periphery region 100B, being alternately arranged with a plurality of isolation structures in the fourth direction D4, for isolating the adjacent ones of the plugs 111, 113. In one embodiment, the plugs 111 for example includes an epitaxial material like silicon, silicon phosphorus (SiP), silicon germanium (SiGe) or germanium (Ge), or a low-resistance metal material like aluminum, titanium, copper or tungsten, but not limited thereto. It is noted that, although the plug array 110 is arrange in a different manner as that of the SN pad array 130, each of the plugs 111 is disposed below each of the first pads 131 in a direction being perpendicular to the substrate 100, to physically contact each of the first pads 131. Each of the plugs 113 is disposed below the second branch pads 139 or the third pads 143, to physically contact a corresponding one of the second branch pads 139 or the third pads 143. The plugs 111 disposed within the cell region 100A are partially extended into the substrate 100 through its bottom thereof, to electrically connect a transistor (not shown in the drawings) disposed within the substrate 100, and to electrically connect the first pads 131 through its top thereof, thereby being configured as storage node contacts (SNCs) of the semiconductor device 10 to further connect to a storage node (SN) being formed subsequently. The plugs 113 disposed within the periphery region 100B are disposed over the insulating layer 102, without contacting the substrate 100 to be served as dummy plugs. It is also noted that, one of the first plugs 131 closest to the second pads 141 or the first branch pads 135, and the plug 111 corresponding thereto have a barycenter C1, C2 respectively, and a minimum distance g1 between the barycenter C1 and the barycenter C2 is greater than a minimum distance g2 between a barycenter C3 of anyone of other first pads 131 and a barycenter C4 of the plug 111 corresponding thereto. Also, a minimum distance g3 between a barycenter C5 of one of the first plugs 131 closest to the second branch pads 139 or the third pads 143 and a barycenter C6 of the plug 111 corresponding thereto is greater than the minimum distance g2, and preferably smaller than the minimum distance g1, but not limited thereto.

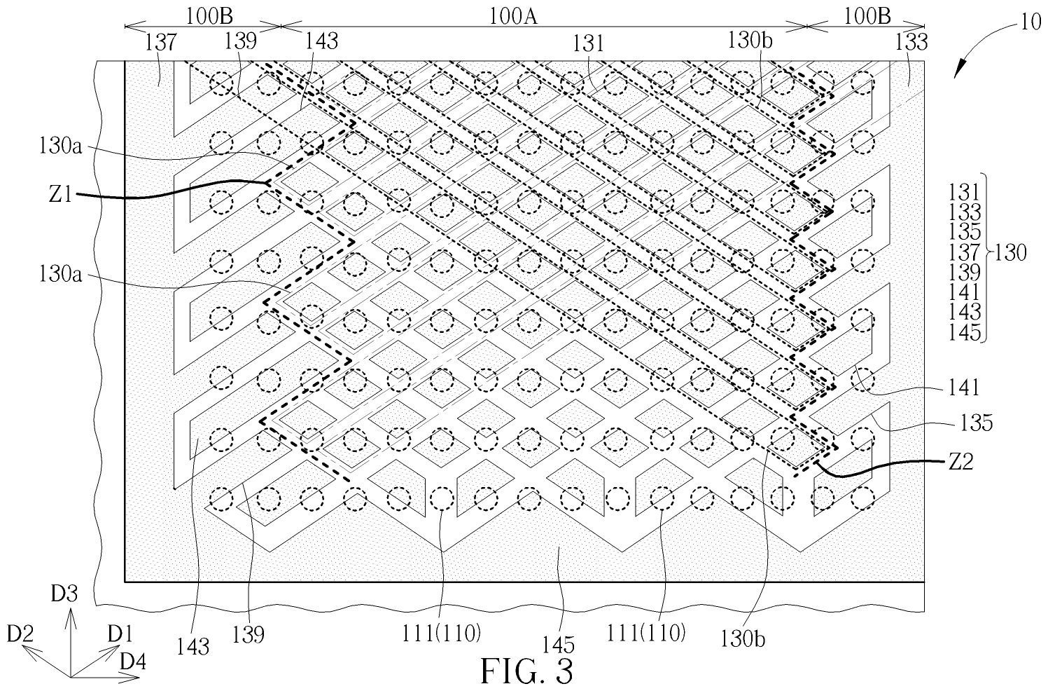

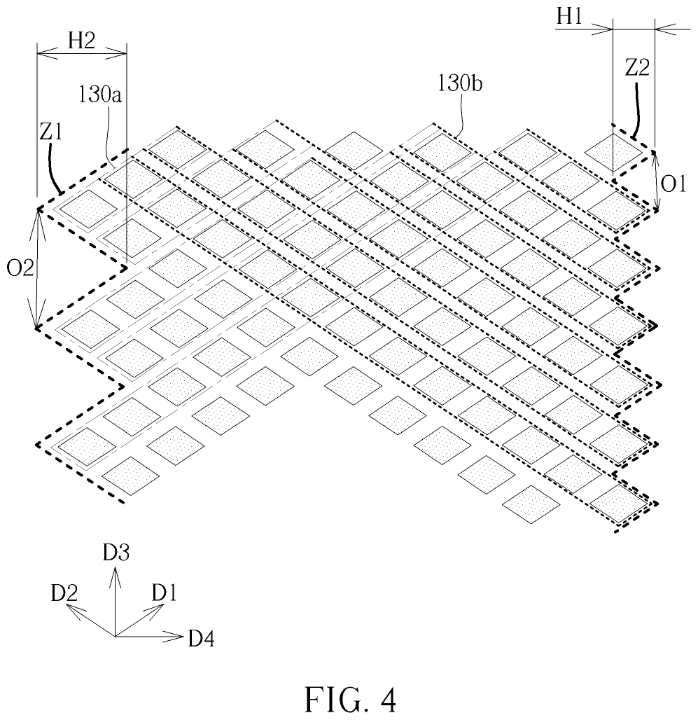

On the other hand, as shown in FIG. 3 and FIG. 4, the first pads 131 are separately arranged into a plurality of columns 130a in the first direction D1, and into a plurality of rows 130b in the second direction D2, thereby presenting in another array arrangement. It is noted that, the first pads 131 within each column 130a, being closest to the second marginal pad 137, are arranged into a first zigzag profile Z1 in the third direction D3, and the first pads 131 within each row 130b, being closest to the first marginal pad 133, are arranged into a second zigzag profile Z2. The first zigzag profile Z1 includes an opening O2 in the third direction D3, the second zigzag profile Z2 includes an opening O1 in the third direction D3, and the opening O2 of the first zigzag profile Z1 is greater than the opening O1 of the second zigzag profile Z2. Also, the first zigzag profile Z1 includes a height H2 in the fourth direction D4, the second zigzag profile Z2 includes a height H1 in the fourth direction D4, and the height H2 is larger than the height H1. The height H1, H2 is namely the height difference between a tip and a bottom of each zigzag profile.

With these arrangements, the semiconductor structure 10 of the preferably embodiment enables to arrange peripheral pads (including the second pads 141, the first branch pads 135, the third pads 143 and the second branch pads 139) at two opposite side of the SN pad array 130, to present in an asymmetric layout as a whole. Accordingly, the minimum distances g1, g2, g3 between the barycenter C1, C3, C5 of each first pad 131 and the barycenter C2, C4, C6 of each plug 111 corresponding thereto will be maintained in a certain range, especially for the minimum distances g1 g3 between the barycenter C1, C5 of the first pad 131 closed to the above-mentioned peripheral pads (for example the second pads 141, the third pads 143, and the second branch pads 139) and the barycenter C2, C6 of the plug 111 corresponding thereto. In this way, it is sufficient to avoid the distance between the barycenter of the first pad 131 and the barycenter of the plug 111 excessive enlarge due to the misalignment between the barycenter C1, C5 of the first pads 131 and the barycenter C2, C6 of the plug 111, such that, the contact area between the first pads 131 and the plugs 111 are seriously affected thereby.

Thus, the semiconductor structure 10 of the present embodiment is allowable to obtain an optimized structure and better functions. People who has ordinary skill in the art would easily understand that various components such as transistor components, word line components and/or bit line components may be additionally arranged within the cell region 100A of the substrate 100, due to practical product requirements. For example, a plurality of capacitors (not shown in the drawings) electrically connected to the first pads 131 may be further disposed above the SN pad array 130, thereby forming a dynamic random access memory (DRAM) device to achieve better device performance, but not limited thereto.

In order to make those having ordinary skills in the art easily understand the semiconductor device 10 according to the present disclosure, a method of fabricating the semiconductor device 10 according to the present disclosure will be further described as follows.

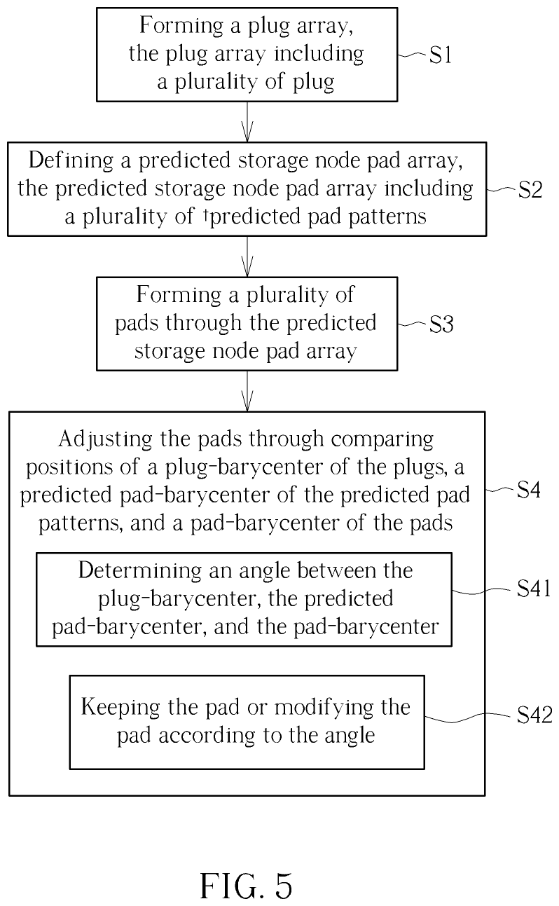

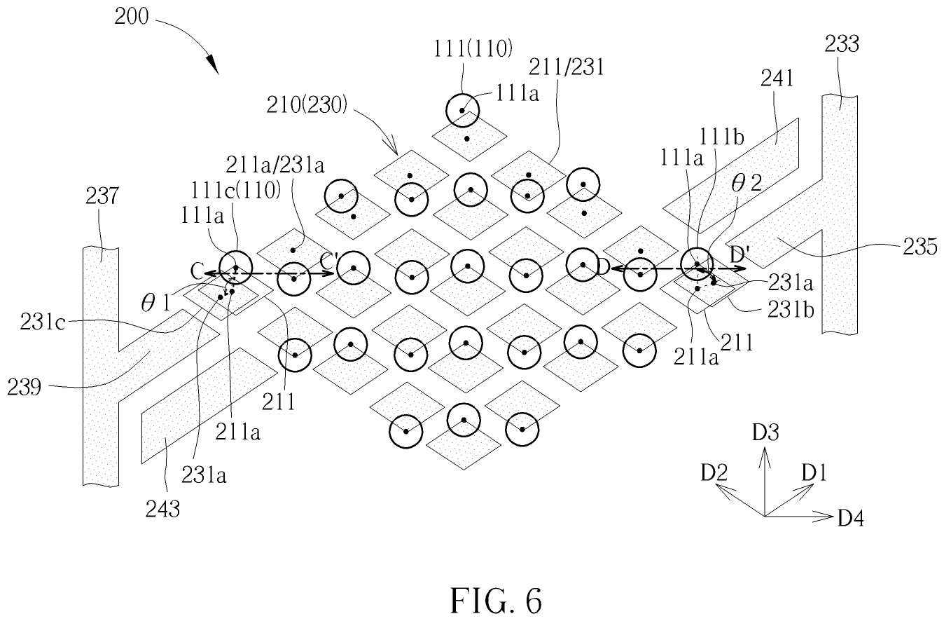

Please refer FIG. 5 to FIG. 9, which are schematic diagrams illustrating a fabricating method of a semiconductor structure 10 according to the preferably embodiment of the present disclosure, with FIG. 5 showing a process flow of the fabricating method of the semiconductor structure 10, with FIGS. 6-9 respectively showing various processing steps of the fabricating method of the semiconductor structure 10. Firstly, as shown in FIG. 5 and FIG. 6, a chip 200 is provided, and the plug array 110 is formed on the chip (as shown in step S1). The plug array 110 includes a plurality of the plugs 111, and a plug-barycenter 111a is defined on each of the plugs 111.

Next, a mask layer (not shown in the drawings) is formed on the chip 200, covering the plug array 110, and a predicted SN pad array 210 is defined on the mask layer, with the predicted SN pad array 210 including a plurality of predicted pad patterns 211 (as shown in step S2). Then, a predicted pad-barycenter 211a is defined on each of the predicted pad patterns 211. The predicted pad patterns 211 respectively overlap the plugs 111 underneath. Those who skilled in the art should fully realize that only partial plugs 111 and partial predicted pad patterns 211 are shown in FIG. 6 of the present embodiment, in order to clearly illustrate the relation between the plugs 111 and the predicted pad patterns 211, and the practical arrangement thereof are not limited thereto. The plugs 111 are for example arranged in the third direction D3 and the fourth direction D4 with are perpendicular with each other, to present in an array arrangement as shown in FIG. 1, and the predicted pad patterns 211 are for example arranged in the first direction D1 and the second direction D2 which are crossed to each other, to present in another array arrangement also shown in FIG. 1, but not limited thereto.

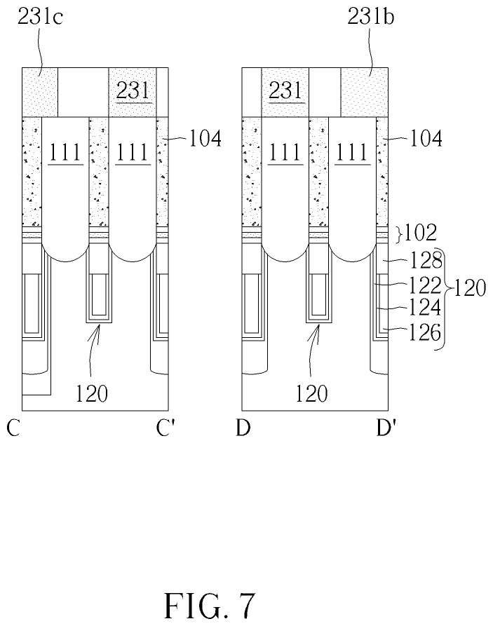

As shown in FIG. 5 and FIG. 7, a photolithography process is performed on the chip 200 through the predicted SN pad array 210, to form a SN pad array 230 including a plurality of pads 231, with the pads 231 respectively overlapping with the plugs 111 underneath. It is noted that, the formation of the pads 231 is accomplished by performing two self-aligned reverse patterning (SARP) processes, to simultaneously form the pads 231, marginal pads 233, 237 having a plurality of branch pads 235, 239 in the first direction D1, and peripheral pads 241, 243 alternately arranged with the branch pads 235, 239 in the third direction D3, as shown in FIG. 6, but not limited thereto. Due to the loading effect of the etching process, at least a portion of the pads 231 has a reduced size or a misaligned position, in comparison with that of the predicted pad patterns 211, and the overlaying rates between the pads 231 and the corresponding plugs 111 will be affected thereby. For example, one pad 231b adjacent to the branch pads 235 or the peripheral pads 241 may slightly shift toward the plug-barycenter 111b of the corresponding plug 111a, in the first direction D1 or in the second direction D2, and another one pad 231c adjacent to the branch pads 239 or the peripheral pads 243 may slightly shift away from the plug-barycenter 111b of the corresponding plug 111c, in the first direction D1 or in the second direction D2, such that, the overlaying rates between the pads 231b, 231c and the corresponding plugs 111a, 111c will be influenced thereby. Although the forming positions of the pads 231b, 231c are all misaligned with the original positions of the predicted pad patterns 211, the pad 231b and the corresponding plug 111b are still overlapped with each other to maintain a certain overlaying rate, as shown in FIG. 6 and FIG. 6. On the other hand, the pad 231c and the corresponding plug 111c cannot maintain the certain overlaying rate.

Following these, the positions of the pads 230 are adjusted through comparing the positions of the plug-barycenter 111a, the predicted pad-barycenter 211a, and the pad-barycenter 231a (as shown in step S4). Precisely speaking, the reducing size or the shift position is easily occurred on the pads 231b, 231c adjacent to the branch pads 235, 239 or the peripheral pads 241, 243, and which may be previously evaluated by defining an angle θ1, θ2 between the plug-barycenter 111a, the predicted pad-barycenter 211a, and the pad-barycenter 231a, as shown in FIG. 6. The angle θ2 between the pad-barycenter 231a of the pad 231c, the predicted pad-barycenter 211a of the corresponding predicted pad pattern 211, and the plug-barycenter 111a of the corresponding plug 111c is greater than the angle θ1 between the pad-barycenter 231a of the pad 231b, the predicted pad-barycenter 211a of the corresponding predicted pad pattern 211, and the plug-barycenter 111a of the corresponding plug 111b. Through these performances, the fabricating method of the present embodiment is allowable to previously estimate the shifting degree of the pads 231 by determining the degree of the angles between the pad-barycenter 231a of one pad 231, the predicted pad-barycenter 211a of the corresponding predicted pad pattern 211, and the plug-barycenter 111a of the corresponding plug 111 (as shown in step S41).

For example, if the angle for example being the angle θ1 as shown in FIG. 6, between the pad-barycenter 231a of one pad 231, the predicted pad-barycenter 211a of the corresponding predicted pad pattern 211, and the plug-barycenter 111a of the corresponding plug 111 is an acute angle being less than 90 degree, the pad 231 still overlaps the corresponding plug 111 in a relative higher overlaying rate, with only a slight shifting occurred, such as the pad 231b as shown in FIG. 6 and FIG. 7. On the other hand, if the angle for example being the angle θ2 as shown in FIG. 6, between the pad-barycenter 231a of one pad 231, the predicted pad-barycenter 211a of the corresponding predicted pad pattern 211, and the plug-barycenter 111a of the corresponding plug 111 is a blunt angle being greater than 90 degree, the pad 231 may be seriously shifted from the original position, being overlapped with the corresponding plug 111 in a relative lower overlaying rate, or being not overlapped with the corresponding plug 111. In this way, the overlaying rate between each pad 231 and the corresponding plug 111 may be previously estimated by determining the angle between the pad-barycenter 231a of one pad 231, the predicted pad-barycenter 211a of f the corresponding predicted pad pattern 211, and the plug-barycenter 111a of the corresponding plug 111, followed by determining to remain the pad 231 or to modify the pad 231. In other words, when the angle between the pad-barycenter 231a of one pad 231, the predicted pad-barycenter 211a of the corresponding predicted pad pattern 211, and the plug-barycenter 111a of the corresponding plug 111 is less than 90 degrees, the pad 231 may be remained. Otherwise, when the angle between the pad-barycenter 231a of one pad 231, the predicted pad-barycenter 211a of the corresponding predicted pad pattern 211, and the plug-barycenter 111a of the corresponding plug 111 is greater than 90 degrees, the pad 231 is then modified thereby.

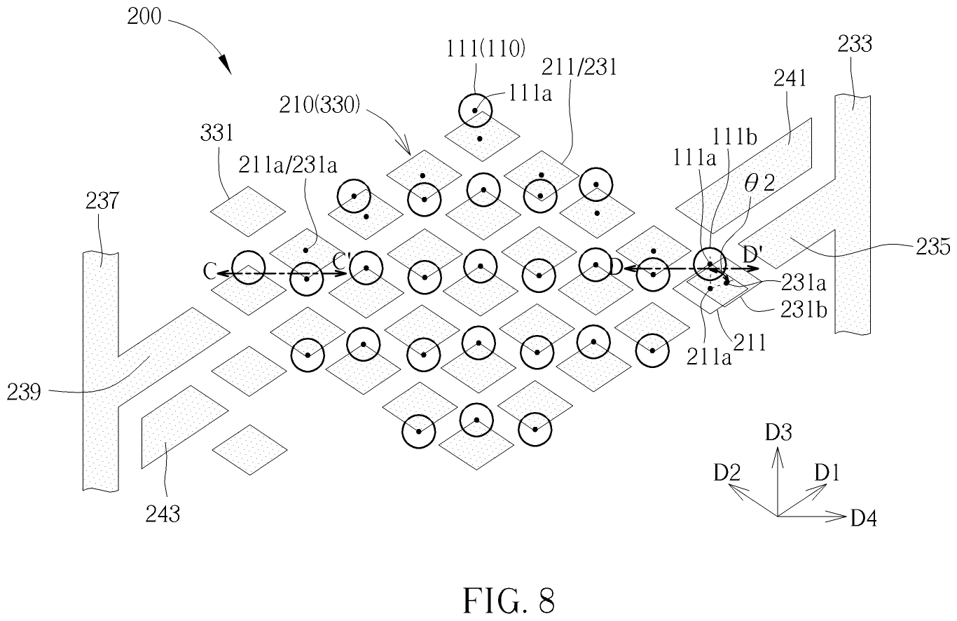

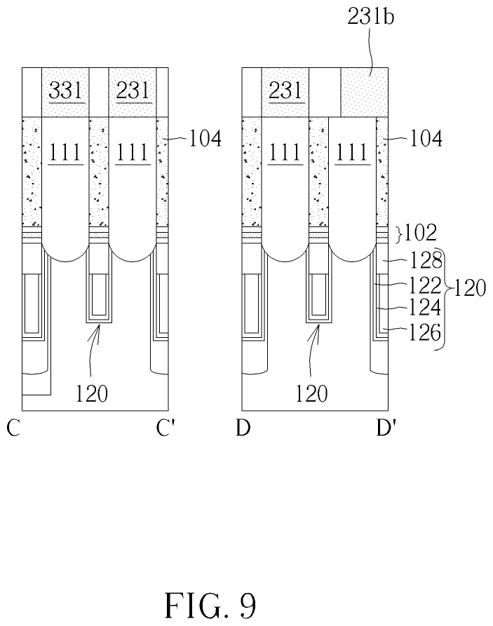

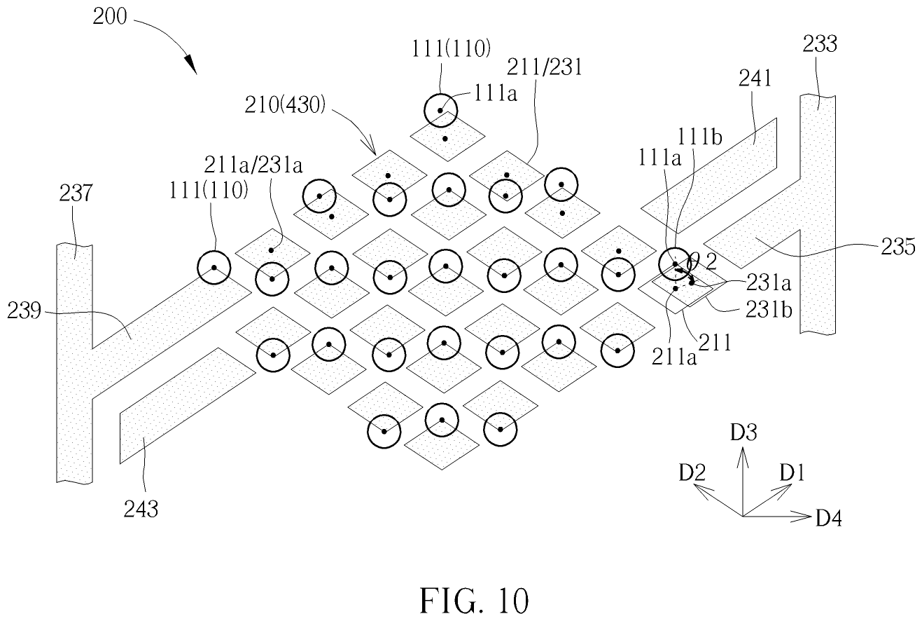

In one embodiment, modifying the pad 231 for example includes removing the pads 231 followed by reforming a new SN pad array 330. Precisely speaking, as shown in FIG. 8, the SN pad array 330 includes the pads 231 originally shown in FIG. 6, and a plurality of pads 331 additionally formed at one side of the pad 231c (having the angle greater than 90 degrees), with the pads 331 being aligned with each other in the third direction, and also being aligned with the pad 231c as shown in FIG. 6 in the third direction D3. Through these performances, the possible etching defects caused by the above-mentioned loading effect will be adjusted by additionally forming the pads 331 at one side of the pad 231c, thereby improving the forming positions of the pads 331 adjacent to the marginal pad 237. Then, all the pads 231, 331 are overlapped with the corresponding plugs underneath in a certain overlaying rate, as shown in FIG. 9, such that, the semiconductor structure formed accordingly will therefore obtain an improved structure to gain a better reliability. In another embodiment, modifying the pad for example includes removing the pad 231, for example the pad 231c as shown in FIG. 6, as well as the pads 231 aligned with the aforementioned pad 231 in the third direction D3, while the angle between the pad-barycenter 231a of the pad 231, the plug-barycenter 111a of the corresponding plug 111, and the predicted pad-barycenter 211a of the corresponding predicted pad pattern 211 is greater than 90 degrees. Those who skilled in the art should fully understand that since the predicted pad patterns 211 of the predicted SN pad array 211 are arranged in the first direction D1 and the second direction D2 into the array arrangement, the pads 231 formed accordingly in the present embodiment will also present in the same array arrangement. Thus, it is preferably to remove a row of the pads 231 at the same time, as modifying the pad 231 that having the angle greater than 90 degrees. That is, a SN pad array 430 is then formed by removing all the pads 231c adjacent to the branch pads 239 or the peripheral pads 243, as shown in FIG. 10, and all the pads 231 remained on the SN pad array 430 will therefore overlap the corresponding plugs 111 underneath in a certain overlaying rate. Then, the semiconductor structure formed thereby may therefore obtain the improved structure and better reliability.

According to the fabricating method of the present embodiment, the possible shifting between each pad 231 and the corresponding plug 111 may be previously estimated by determining the angle between the pad-barycenter 231a of one pad 231b, 231c, the predicted pad-barycenter 211a of the corresponding predicted pad pattern 211, and the plug-barycenter 111a of the corresponding plug 111, followed by keeping the pad 231 or modifying the pad 231. Also, since the above-mentioned loading effect of the etching is generally occurred on the pads 231 at one side of the SN pad array 230, the pad-barycenter 231a of the pads 231c at one side of the SN pad array 230 may be seriously shifted from the plug-barycenter 111a of the corresponding plug 111, and the overlaying rate between the pads 231c and the plugs 111 will be dramatically affected thereby. Thus, the pads 231c only disposed at one side of the SN pad array 230 are modified, and the new SN pad array formed subsequently will thereof present in an asymmetric layout, such as the SN pad array 130 as shown in FIG. 1. Through these performances, the fabricating method of the present embodiment is allowable to form the semiconductor structure 10 with the optimized structure and functions, which enables to be applied on forming a DRAM device subsequently, to achieve better performances thereby.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a storage node pad array, the storage node pad array comprising:
a plurality of first pads separately disposed in a first direction and in a second direction;
a first marginal pad disposed at one side of the storage node pad array, the first marginal pad comprising a plurality of first branch pads extending in the first direction;
a second marginal pad disposed at another side of the storage node pad array being opposite to the first marginal pad, the second marginal pad comprising a plurality of second branch pads extending in the first direction;
a plurality of second pads separately disposed between the first branch pads in a third direction; and
a plurality of third pads separately disposed between the second branch pads in the third direction;
wherein a length of the second pads in the first direction is smaller than a length of the third pads in the first direction.

2. The semiconductor structure according to claim 1, wherein one of the first pads is sandwiched between the second branch pads or between the third pads, and none of the first pads is sandwiched between the first branch pads or between the second pads.

3. The semiconductor structure according to claim 1, wherein the first pads comprise a first length in the first direction, the second pads comprise a second length in the first direction, and the third pad comprise a third length in the first direction, wherein the first length, the second length and the third length are all different from each other.

4. The semiconductor structure according to claim 1, wherein end-portions of each of the second pads and each of the first branch pads are aligned with each other in the third direction, and end-portions of each of the third pads and each of the second branch pads are partially misaligned with each other.

5. The semiconductor structure according to claim 1, further comprising:
a plug array disposed below the storage node pad array, and the plug array comprising:
a plurality of plugs disposed below the first pads, the second pads and the third pads, wherein each of the first pads, each of the second pads, and each of the third pad at least partially overlap a corresponding one of the plugs underneath, respectively.

6. The semiconductor structure according to claim 5, wherein a distance between a barycenter of one of the first pads being closest to the second pads, the first branch pads, the third pads or the second branch pads in the first direction, and a barycenter of one of the plugs corresponding thereto is greater than a distance between a barycenter of another one of the first pads and a barycenter of one of the plugs corresponding thereto.

7. A semiconductor structure, comprising:
a storage node pad array, the storage node pad array comprising:
a plurality of first pads separately arranged into a plurality of columns in a first direction, and arranged into a plurality of rows in a second direction;
a first marginal pad disposed at one side of the storage node pad array, the first marginal pad comprising a plurality of first branch pads; and
a second marginal pad disposed at another side of the storage node pad array being opposite to the first marginal pad, the second marginal pad comprising a plurality of second branch pads;
wherein the first pads within each of the columns closest to the first marginal pad comprises a first zigzag profile, the first pads within each of the columns closest to the second marginal pad comprises a second zigzag profile, and the second zigzag profile is different from the first zigzag profile.

8. The semiconductor structure according to claim 7, wherein an opening of the first zigzag profile is greater than an opening of the second zigzag profile.

9. The semiconductor structure according to claim 7, wherein a height of the first zigzag profile is greater than a height of the second zigzag profile.

10. The semiconductor structure according to claim 7, the storage node pad array further comprising:
a plurality of second pads separately disposed between the first branch pads in a third direction; and
a plurality of third pads separately disposed between the second branch pads in the third direction, wherein the first pads comprise a first length in the first direction, the second pads comprise a second length in the first direction, the third pads comprise a third length in the first direction, and the first length, the second length, and the third length are all different from each other.

11. The semiconductor structure according to claim 10, wherein one of the first pads is sandwiched between the second branch pads or between the third pads in the third direction, and none of the first pads is sandwiched between the first branch pads or between the second pads in the third direction.

12. The semiconductor structure according to claim 10, further comprising:
a plug array comprising:
a plurality of plugs disposed below the first pads, the second pads and the third pads, wherein each of the first pads, each of the second pads, and each of the third pad at least partially overlap a corresponding one of the plugs underneath, respectively.

13. The semiconductor structure according to claim 12, wherein a distance between a barycenter of one of the first pads being closest to the second pads, the first branch pads, the third pads or the second branch pads in the first direction, and a barycenter of one of the plugs corresponding thereto is greater than a distance between a barycenter of another one of the first pads and a barycenter of one of the plugs corresponding thereto.

14. A fabricating method of a semiconductor structure, comprising:
forming a plug array on a chip, the plug array comprising a plurality of plugs, and each of the plugs comprising a plug-barycenter being defined thereon;
defining a predicted storage node pad array on the chip, wherein the predicted storage node pad array comprises a plurality of predicted pad patterns, and each of the predicted pad patterns comprises a predicted pad-barycenter being defined thereon;
forming a plurality of pads on the plugs through the predicted storage node pad array, each of the pads overlapping each of the plugs and comprising a pad-barycenter; and
adjusting the pads through comparing positions of the plug-barycenter, the predicted pad-barycenter, and the pad-barycenter.

15. The semiconductor structure according to claim 14, adjusting the pads further comprising:
defining an angle between the pad-barycenter of one of the pads, and the plug-barycenter and the predicted pad-barycenter corresponding thereto; and
modifying the one of the pads or keeping the one of the pads through the angle.

16. The semiconductor structure according to claim 15, further comprising:
forming a storage node pad array, the storage node pad array comprising:
a plurality of first pads separately arranged into a plurality of columns in a first direction, and a plurality of rows in a second direction;
a plurality of second pads arranged at a first side of the first pads; and
a plurality of third pads arranged at a second side of the first pads, wherein the first pads comprise a first length in the first direction, the second pads comprise a second length in the first direction, the third pads comprise a third length in the first direction, and the first length, the second length, and the third length are all different from each other.

17. The semiconductor structure according to claim 16, further comprising:
keeping the one of the pads while the angle is less than 90 degrees.

18. The semiconductor structure according to claim 16, further comprising:
modify the one of the pads while the angle is greater than 90 degrees.

19. The semiconductor structure according to claim 18, modifying the pad further comprising:
additionally forming a column of the first pads being aligned with each other in the third direction, on the plugs.

20. The semiconductor structure according to claim 18, modifying the pad further comprising:
removing the first pads closest to the second pads or the third pads in the first direction.
